(19) United States
(12) Patent Application Publication
(10) Pub. No.: US 2007/0101225 A1
(43) Pub. Date: May 3, 2007

(54) Circuit and method of testing semiconductor memory devices

(75) Inventors: Gil-Shin Moon, Hwaseong-si (KR); Seok-Won Hwang, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/581,233

(22) Filed: Oct. 16, 2006

(30) Foreign Application Priority Data
Oct. 17, 2005 (KR) 10-2005-0097377

(51) Int. Cl. G06F 11/00; G01R 31/28

(52) U.S. Cl. 714/736

(57) ABSTRACT

A circuit for testing a semiconductor memory device includes a data comparator and a signal aligner. The data comparator compares a first output data and a second output data provided from an output buffer circuit. The data comparator determines whether logical states of the first output data and the second output data are identical to generate a comparison signal. The signal aligner aligns the first output data and the comparison signal, and generates a plurality of test signals in response to a clock signal. The test signals includes an even bit test data, an odd bit test data, an even bit comparison test data and an odd bit comparison test data. The even bit data and the odd bit data are simultaneously tested by using one pattern, and a correct test result is yielded even when test data are all inverted.

### CROSS-REFERENCE TO RELATED APPLICATIONS

This application claims priority under 35 U.S.C § 119 to commonly owned Korean Patent Application No. 10-2005-0097377, filed on Oct. 17, 2005, in the Korean Intellectual Property Office, the disclosure of which is incorporated herein by reference in its entirety.

### BACKGROUND OF THE INVENTION

1. Field of the Invention

The present invention relates to a semiconductor memory device, and more particularly to a circuit and a method of testing semiconductor memory devices.

2. Description of the Related Art

A conventional semiconductor memory device can test a write operation and a read operation by using a tester for inspecting every memory cell. As a capacity of the semiconductor memory device is increased, a time for testing is increased. For example, if 1 clock cycle is 90 ns, it takes about 24 seconds to write and read data “0” and then write and read data “1” with respect to every memory cell in a 64 M DRAM. In mass production of semiconductor memory devices, the time for testing the produced memory devices is so much increased that a unit cost of testing can be increased and productivity can be decreased. Recently, a merged DQ (MDQ) test technique has been applied for increasing a number of bits that can be tested at once. An example of the MDQ test technique is disclosed in Korean Patent Laid-Open Publication No. 10-2001-0063184.

The semiconductor memory device operating at high speed is tested in a high speed clock (HSC) test mode by using a conventional test device operating at a low frequency. However, an even-numbered data test pattern and an odd-numbered data test pattern cannot be tested at once in conventional test devices. Therefore, the semiconductor memory device operating at high speed requires a relatively long test time, thereby increasing the cost for testing.

Furthermore, using the above approach and conventional test device, there is a risk that a failed memory device passes the test when every read data represents an inverted value of the write data in the MDQ test mode.

### SUMMARY OF THE INVENTION

Some example embodiments in accordance with aspects of the present invention provide a circuit for testing a semiconductor memory device, which is capable of simultaneously testing even bit data and odd bit data by using one test pattern in a high speed clock test mode and can yield a correct test result even when test data are all inverted.

Some example embodiments in accordance with aspects of the present invention provide a semiconductor memory device having a test circuit, which is capable of simultaneously testing even bit data and odd bit data by using one test pattern in a high speed clock test mode and can yield a correct test result even when test data are all inverted.

Some example embodiments in accordance with aspects of the present invention provide a method of testing a semiconductor memory device, capable of simultaneously testing even bit data and odd bit data by using one test pattern in a high speed clock test mode and can yield a correct test result even when test data are all inverted.

In accordance with one aspect of the present invention, provided is a circuit for testing a semiconductor memory device that includes a data comparator and a signal aligner. The data comparator is configured to compare a first output data and a second output data provided from an output buffer circuit. The output buffer circuit is configured to determine whether logical states of the first output data and the second output data are identical to generate a comparison signal. The signal aligner is configured to align the first output data and the comparison signal in response to a clock signal to generate a plurality of test signals. The test signals can include an even bit test data, an odd bit test data, an even bit comparison test data and an odd bit comparison test data.

The signal aligner can be configured to align the first output data and the comparison signal by latching the first output data and the comparison signal, and outputs the test signals in synchronization with the clock signal.

The even bit test data and the odd bit test data can be simultaneously outputted in response to a first edge of the clock signal, the first edge corresponding to one of a rising edge and a falling edged of the clock signal.

The even bit comparison test data and the odd bit comparison test data can be simultaneously outputted in response to a first edge of the clock signal, the first edge corresponding to one of a rising edge and a falling edged of the clock signal.

The even bit test data, the odd bit test data, the even bit comparison test data and the odd bit comparison test data can be outputted through different output pads from a set of output pads.

The first output data can comprise a third output data and a fourth output data, and the second output data can comprise a fifth output data and a sixth output data.

The even bit test data can correspond to an even bit of the third output data, and the odd bit test data can correspond to an odd bit of the fourth output data.

The even bit comparison test data can correspond to the comparison signal when the third, fourth, fifth and sixth output data are even bit data and the odd bit comparison test data can correspond to the comparison signal when the first, second, third and fourth output data are odd bit data.

The data comparator can be configured to compare the third, fourth, fifth and sixth output data to generate the comparison signal.

The data comparator can comprise a first XOR gate configured to perform an XOR operation on the third and fourth output data to generate a first logic signal, a second XOR gate configured to perform an XOR operation on the fifth and sixth output data to generate a second logic signal, and an OR gate configured to perform an OR operation on the first and second logic signals to generate the comparison signal.

The semiconductor memory device can have an X32 output data structure, and the X32 output data structure can include four data groups, each data group including eight data.

The semiconductor memory device can operate with a burst length of four.

In accordance with another aspect of the present invention, provided is a semiconductor memory device that includes a memory core, an Input/Output sense amplifier, an output buffer circuit and a test circuit. The memory core includes a memory cell array. The Input/Output sense amplifier is configured to amplify data outputted from the memory core to generate a sense output signal. The output buffer circuit is configured to buffer the sense output signal to generate a plurality of output data. The test circuit is configured to process the plurality of output data to generate a plurality of test signals. The test circuit includes a data comparator and a signal aligner. The data comparator is configured to compare a first output data and a second output data. The data comparator is also configured to determine whether logic states of the first and the second output data are identical to generate a comparison signal. The signal aligner is configured to align the first output data and the comparison signal and to generate the test signals in response to a clock signal. The test data can include even bit test data, odd bit test data, even bit comparison test data and odd bit comparison test data.

In accordance with yet another aspect of the present invention, provided is a method of testing a semiconductor memory device. The method includes: comparing a first output data and a second output data outputted from a sense amplifier to generate a comparison signal; and aligning the first output data and the comparison signal to generate a plurality of test signals in response to a clock signal.

The test signals can include even bit test data, odd bit test data, even bit comparison test data and odd bit comparison test data.

Aligning the first output data and the comparison signal can comprise latching the first output data and the comparison signal to output the test signals in synchronization with the clock signal.

The even bit test data and the odd bit test data can be simultaneously outputted in response to a first edge of the clock signal, the first edge corresponding to one of a rising edge and a falling edged of the clock signal.

Therefore, in accordance with various aspects of the present invention, the even bit data and the odd bit data can be simultaneously tested by using one pattern, and a correct test result can be yielded even when test data are all inverted.

### BRIEF DESCRIPTION OF THE DRAWINGS

Various aspects of the invention will become more apparent in view of the attached drawing figures, which are provided by way of example, not by way of limitation, in which:

FIG. 1 is a timing diagram illustrating clocks and test pattern data in a test device of a semiconductor memory device.

FIG. 2 is a table showing examples of output data of BL4 referred to in FIG. 1.

FIG. 3 is a schematic view illustrating an embodiment of an output buffer circuit of the semiconductor memory device supporting an X32 data structure according to aspects of the present invention.

FIG. 4 is a block diagram illustrating an embodiment of an arrangement of output buffers used in a test circuit of the semiconductor memory device according to aspects of the present invention.

FIGS. 5 through 12 are block diagrams respectively illustrating embodiments of the test circuit of the semiconductor memory device according to aspects of the present invention.

FIG. 13 is a circuit diagram illustrating an embodiment of a data comparator in the test circuit of the semiconductor memory device in FIG. 5.

FIG. 14 is a block diagram illustrating an embodiment of a semiconductor memory device comprising the test circuits of FIGS. 5 through 12.

### DESCRIPTION OF THE EMBODIMENTS

Detailed illustrative embodiments according to aspects of the present invention are disclosed herein. However, specific structural and functional details disclosed herein are merely representative for purposes of describing example embodiments of the present invention. This invention can, therefore, be embodied in many alternate forms and should not be construed as limited to the embodiments set forth herein.

Accordingly, while the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention. Like numbers refer to like elements throughout the description of the figures.

It will be understood that, although the terms first, second, etc. can be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent”, etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including”, when used herein, specify the presence of stated features, integers, steps, operations, elements, and/or components, but do not preclude the presence or addition of one or more other features, integers, steps, operations, elements, components, and/or groups thereof.

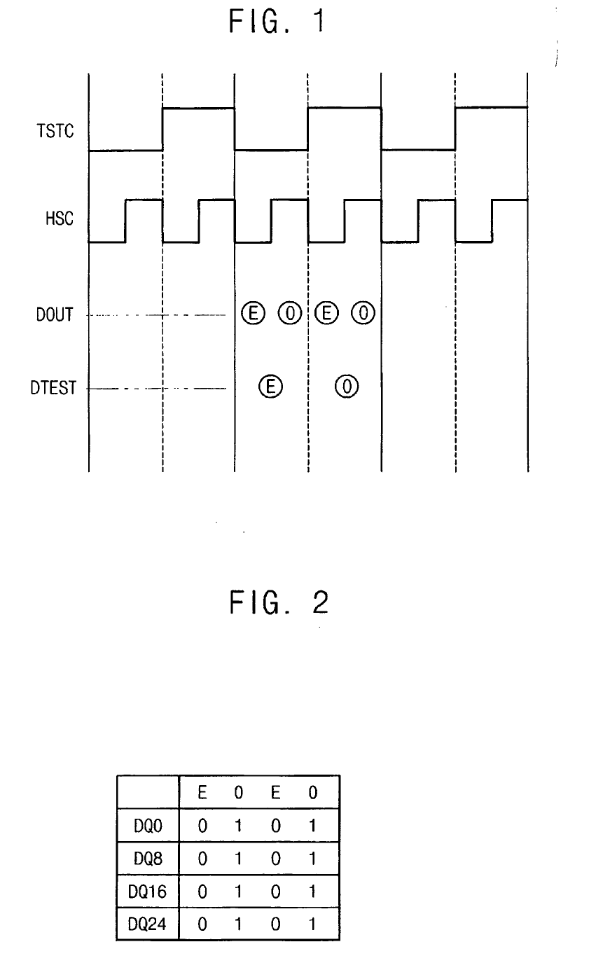

FIG. 1 is a timing diagram illustrating clock signals and test pattern data in a test device of a semiconductor memory device. Referring to FIG. 1, a frequency of a high speed clock signal HSC is twice that of a frequency of a tester clock signal TSTC. For example, output data DOUT for testing can be outputted by a unit of four bits (E, O, E and O) where “E” indicates even-numbered data and “O” indicates odd-numbered data. However, test data DTEST are tested by a unit of two bits (E and O). In case of output data of burst length 4 (BL4), four data (E, O, E and O) are output for 1 cycle of the tester clock signal TSTC. For example, in four bit serial data, first and third bits can be represented as “E”, and second and fourth bits can be represented as “O”. However, only two data (E and O) can be tested for one cycle of the tester clock signal TSTC in the conventional test devices.

FIG. 2 is a table showing examples of output data of BL4. Referring to FIG. 2, each output data DQ0, DQ8, DQ16 and DQ24 includes four bits (E, O, E and O). Since the 4 bit number typically begins with 0, the first bit (bit number 0) and the third bit (bit number 2) can be referred to as even bits and the second bit (bit number 1) and the fourth bit (bit number 3) can be referred to as odd bits. For example, when the output data DQ0 are 0101, the even bits are “0” and the odd bits are “1.”

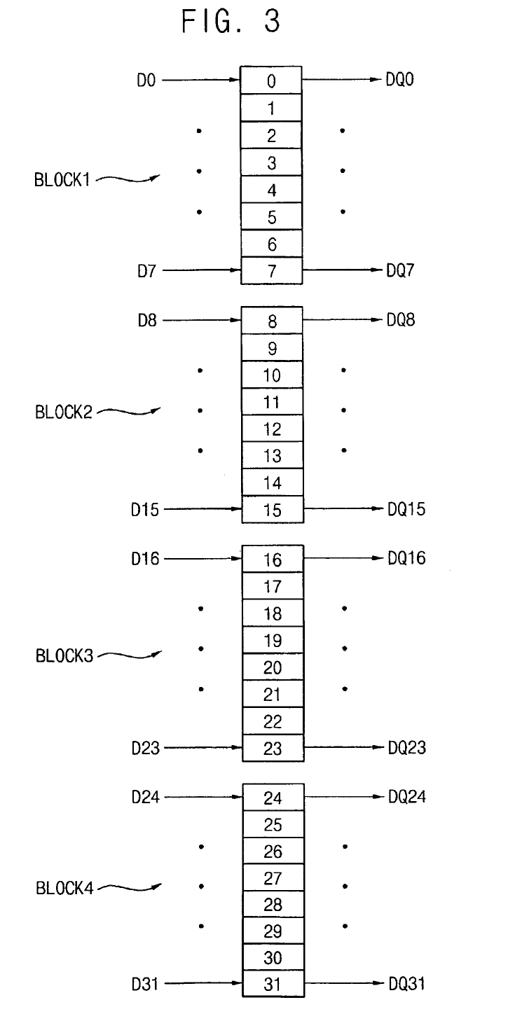

FIG. 3 is a schematic view illustrating an embodiment of an output buffer circuit of the semiconductor memory device supporting an X32 data structure. Referring to FIG. 3, the output buffer circuit buffers 32 bits of received data, D0 through D31, and generates 32 output data, DQ0 through DQ31. The output buffer circuit includes first through fourth blocks, BLOCK1 through BLOCK4, and each block includes eight buffers. The first block BLOCK1 includes buffers zero through seven, the second block BLOCK2 includes buffers eight through fifteen, the third block BLOCK3 includes buffers sixteen through twenty-three, and the fourth block BLOCK4 includes buffers twenty-four through thirty-one. An output buffer circuit can be configured differently from the illustrative embodiment of FIG. 3. For example, an output buffer circuit can include eight blocks, each having four buffers.

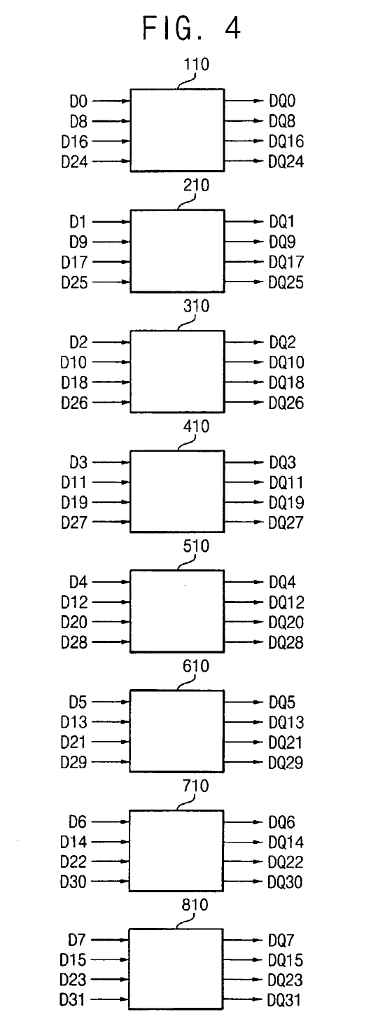

FIG. 4 is a block diagram illustrating an embodiment depicting an arrangement of output buffers that can be included in a circuit for testing semiconductor memory devices, according to aspects of the present invention.

Referring to FIGS. 3 and 4, a first output buffer circuit 110 includes a first buffer 0 of the first block BLOCK1, a first buffer 8 of the second block BLOCK2, a first buffer 16 of the third block BLOCK3 and a first buffer 24 of the fourth block BLOCK4. A second output buffer circuit 210 includes a second buffer 1 of the first block BLOCK1, a second buffer 9 of the second block BLOCK2, a second buffer 17 of the third block BLOCK3 and a second buffer 25 of the fourth block BLOCK4. A third output buffer circuit 310 includes a third buffer 2 of the first block BLOCK1, a third buffer 10 of the second block BLOCK2, a third buffer 18 of the third block BLOCK3 and a third buffer 26 of the fourth block BLOCK4. A fourth output buffer circuit 410 includes a fourth buffer 3 of the first block BLOCK1, a fourth buffer 11 of the second block BLOCK2, a fourth buffer 19 of the third block BLOCK3 and a fourth buffer 27 of the fourth block BLOCK4. A fifth output buffer circuit 510 includes a fifth buffer 4 of the first block BLOCK1, a fifth buffer 12 of the second block BLOCK2, a fifth buffer 20 of the third block BLOCK3 and a fifth buffer 28 of the fourth block BLOCK4. A sixth output buffer circuit 610 includes a sixth buffer 5 of the first block BLOCK1, a sixth buffer 13 of the second block BLOCK2, a sixth buffer 21 of the third block BLOCK3 and a sixth buffer 29 of the fourth block BLOCK4. A seventh output buffer circuit 710 includes a seventh buffer 6 of the first block BLOCK1, a seventh buffer 14 of the second block BLOCK2, a seventh buffer 22 of the third block BLOCK3 and a seventh buffer 30 of the fourth block BLOCK4. An eighth output buffer circuit 810 includes an eighth buffer 7 of the first block BLOCK1, an eighth buffer 15 of the second block BLOCK2, an eighth buffer 23 of the third block BLOCK3 and an eighth buffer 31 of the fourth block BLOCK4.

The first output buffer circuit 110 buffers four received data D0, D8, D16 and D24 and generates four output data DQ0, DQ8, DQ16 and DQ24. The second output buffer circuit 210 buffers four received data D1, D9, D17 and D25 and generates four output data DQ1, DQ9, DQ17 and DQ25. The third output buffer circuit 310 buffers four received data D2, D10, D18 and D26 and generates four output data DQ2, DQ10, DQ18 and DQ26. The fourth output buffer circuit 410 buffers four received data D3, D11, D19 and D27 and generates four output data DQ3, DQ11, DQ19 and DQ27. The fifth output buffer circuit 510 buffers four received data D4, D12, D20 and D28 and generates four output data DQ4, DQ12, DQ20 and DQ28. The sixth output buffer circuit 610 buffers four received data D5, D13, D21 and D29 and generates four output data DQ5, DQ13, DQ21 and DQ29. The seventh output buffer circuit 710 buffers four received data D6, D14, D22 and D30 and generates four output data DQ6, DQ14, DQ22 and DQ30. The eighth output buffer circuit 810 buffers four received data D7, D15, D23 and D31 and generates four output data DQ7, DQ15, DQ23 and DQ31.

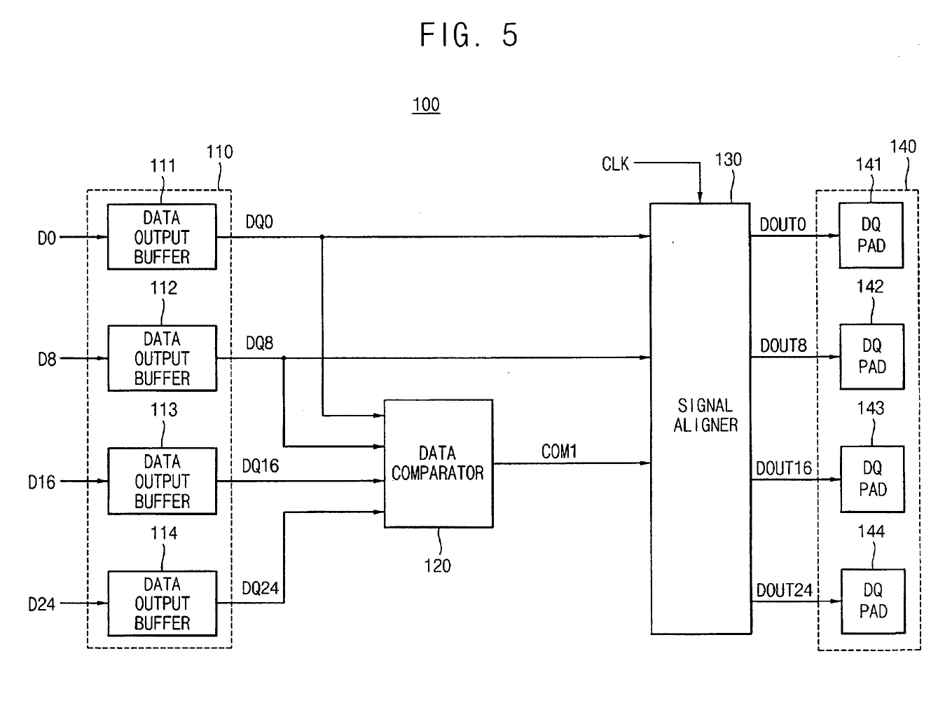

FIG. 5 is a block diagram illustrating an embodiment of a circuit for generating test data DOUT0, DOUT8, DOUT16 and DOUT24 based on output data DQ0, DQ8, DQ16 and DQ24 of the first output buffer circuit 110 in FIG. 4. Referring to FIG. 5, a test circuit 100 of a semiconductor memory device includes an output buffer circuit 110, a data comparator 120, a signal aligner 130 and an output pad circuit 140.

The output buffer circuit 110, which corresponds to the output buffer circuit 110 in FIG. 4, includes data output buffers 111,112, 113 and 114.

The data comparator 120 compares the output data DQ0, DQ8, DQ16 and DQ24 of the output buffer circuit 110 including first data output buffers 111 and 112 and second data output buffers 113 and 114, and generates a comparison signal COM1 The signal aligner 130 aligns the output data DQ0 and DQ8 of the first data output buffers 111 and 112 and the comparison signal COM1 in response to a clock signal CLK and generates the test data DOUT0, DOUT8, DOUT16 and DOUT24. Each of the test data DOUT0, DOUT8, DOUT16 and DOUT24 includes even bit test data, odd bit test data, even bit comparison test data and odd bit comparison test data, respectively.

The test data DOUT0, DOUT8, DOUT16 and DOUT24 can be transmitted to a test device through output pads 141, 142, 143 and 144 included in the output pad circuit 140, respectively.

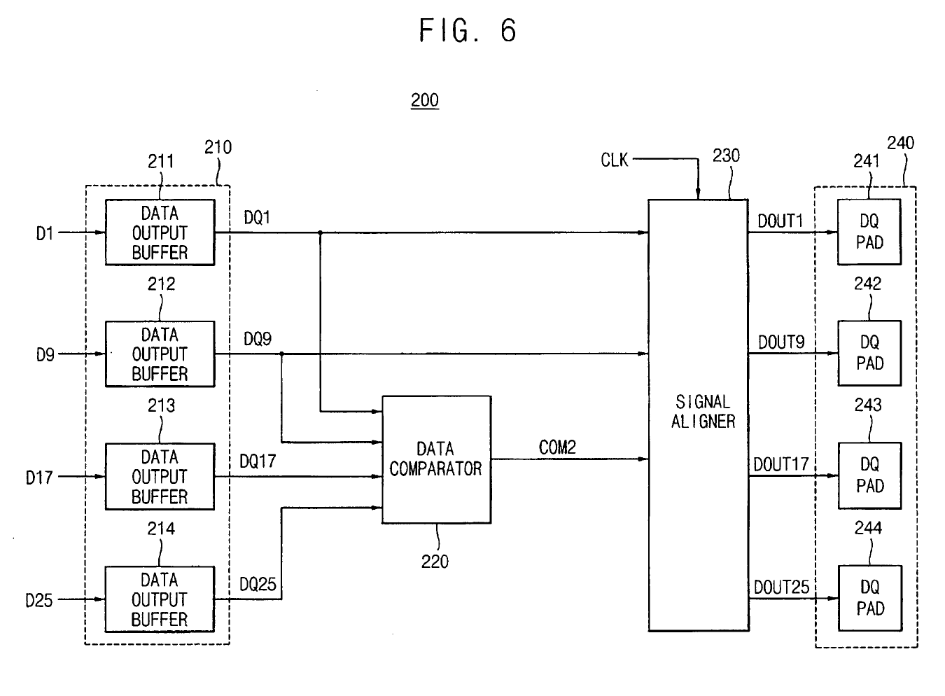

FIG. 6 is a block diagram illustrating an embodiment of a circuit for generating test data DOUT1, DOUT9, DOUT17 and DOUT25 based on output data DQ1, DQ9, DQ17 and DQ25 of the second output buffer circuit 210 in FIG. 4. Referring to FIG. 6, a test circuit 200 of the semiconductor memory device includes an output buffer circuit 210, a data comparator 220, a signal aligner 230 and an output pad circuit 240.

The output buffer circuit 210, which corresponds to the output buffer circuit 210 in FIG. 4, includes data output buffers 211,212,213 and 214.

The data comparator 220 compares the output data DQ1, DQ9, DQ17 and DQ25 of the output buffer circuit 210 including first data output buffers 211 and 212 and second data output buffers 213 and 214, and generates a comparison signal COM2.

The signal aligner 230 aligns the output data DQ1 and DQ9 of the first data output buffers 211 and 212 and the comparison signal COM2 in response to the clock signal CLK and generates the test data DOUT1, DOUT9, DOUT17 and DOUT25. Each of the test data DOUT1, DOUT9, DOUT17 and DOUT25 comprise even bit test data, odd bit test data, even bit comparison test data and odd bit comparison test data, respectively.

The test data DOUT1, DOUT9, DOUT17 and DOUT25 can be transmitted to a test device through output pads 241, 242, 243 and 244 included in the output pad circuit 240, respectively.

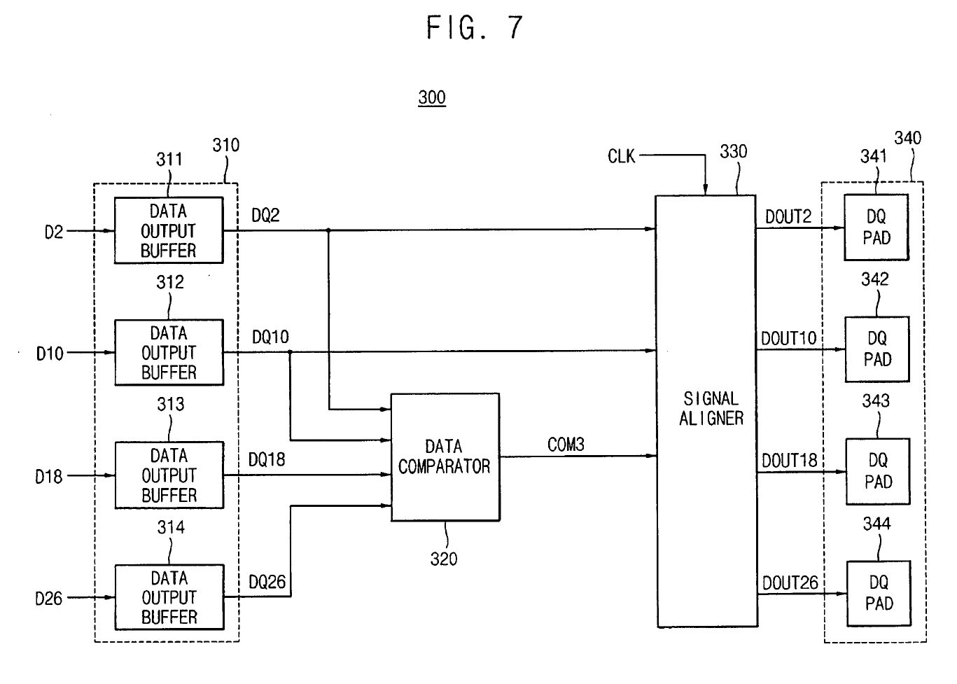

FIG. 7 is a block diagram illustrating an embodiment of a circuit for generating test data DOUT2, DOUT10, DOUT18 and DOUT26 based on output data DQ2, DQ10, DQ18 and DQ26 of the third output buffer circuit 310 in FIG. 4. Referring to FIG. 7, a test circuit 300 of a semiconductor memory device includes an output buffer circuit 310, a data comparator 320, a signal aligner 330 and an output pad circuit 340.

The output buffer circuit 310, which corresponds to the output buffer circuit 310 in FIG. 4, includes data output buffers 311, 312, 313 and 314.

The data comparator 320 compares the output data DQ2, DQ10, DQ18 and DQ26 of the output buffer circuit 310 including first data output buffers 311 and 312 and second data output buffers 313 and 314 and generates a comparison signal COM3.

The signal aligner 330 aligns the output data DQ2 and DQ10 of the first data output buffers 311 and 312 and the comparison signal COM3 in response to the clock signal CLK and generates the test data DOUT2, DOUT10, DOUT18 and DOUT26. Each of the test data DOUT2, DOUT10, DOUT18 and DOUT26 includes even bit test data, odd bit test data, even bit comparison test data and odd bit comparison test data, respectively.

The test data DOUT2, DOUT10, DOUT18 and DOUT26 can be transmitted to a test device through output pads 341, 342, 343 and 344 included in the output pad circuit 140, respectively.

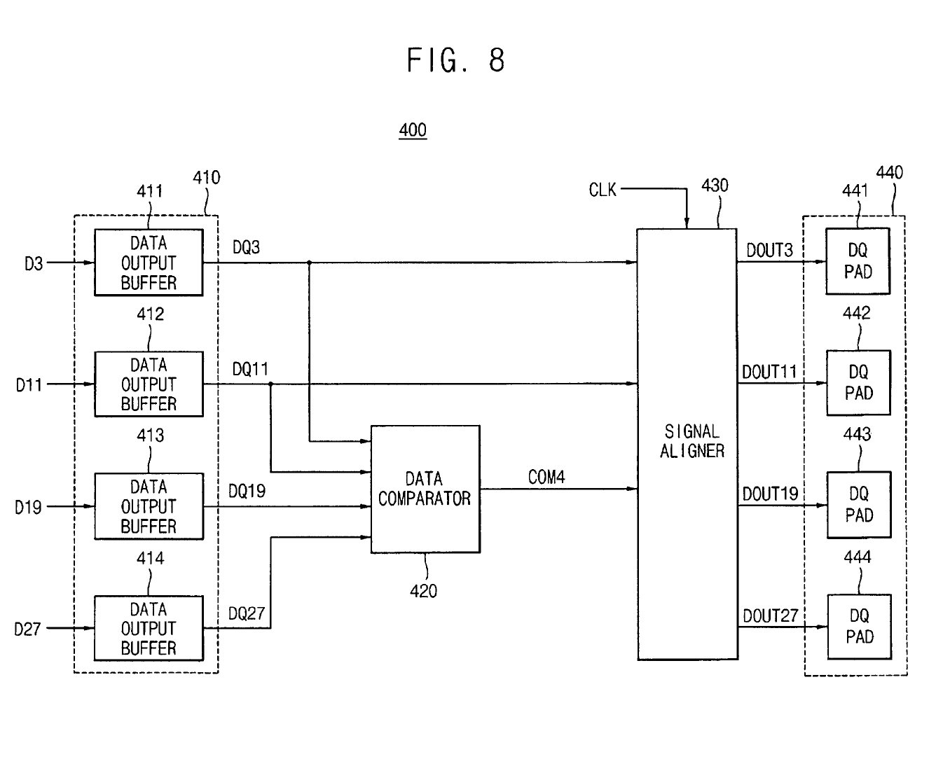

FIG. 8 is a block diagram illustrating an embodiment of a circuit for generating test data DOUT3, DOUT11, DOUT19 and DOUT27 based on output data DQ3, DQ11, DQ19 and DQ27 of the fourth output buffer circuit 410 in FIG. 4. Referring to FIG. 8, a test circuit 400 of the semiconductor memory device comprises an output buffer circuit 410, a data comparator 420, a signal aligner 430 and an output pad circuit 440.

The output buffer circuit 410, which corresponds to the output buffer circuit 410 in FIG. 4, includes data output buffers 411,412, 413 and 414.

The data comparator 420 compares the output data DQ3, DQ11, DQ19 and DQ27 of the output buffer circuit 410 including first data output buffers 411 and 412 and second data output buffers 413 and 414, and generates a comparison signal COM4.

The signal aligner 430 aligns the output data DQ3 and DQ11 of the first data output buffers 411 and 412 and the comparison signal COM4 in response to the clock signal CLK and generates the test data DOUT3, DOUT11, DOUT19 and DOUT27. Each of the test data DOUT3, DOUT11, DOUT19 and DOUT27 includes even bit test data, odd bit test data, even bit comparison test data and odd bit comparison test data, respectively. The test data DOUT3, DOUT11, DOUT19 and DOUT27 can be transmitted to a test device through output pads 441, 442, 443 and 444 included in the output pad circuit 440, respectively.

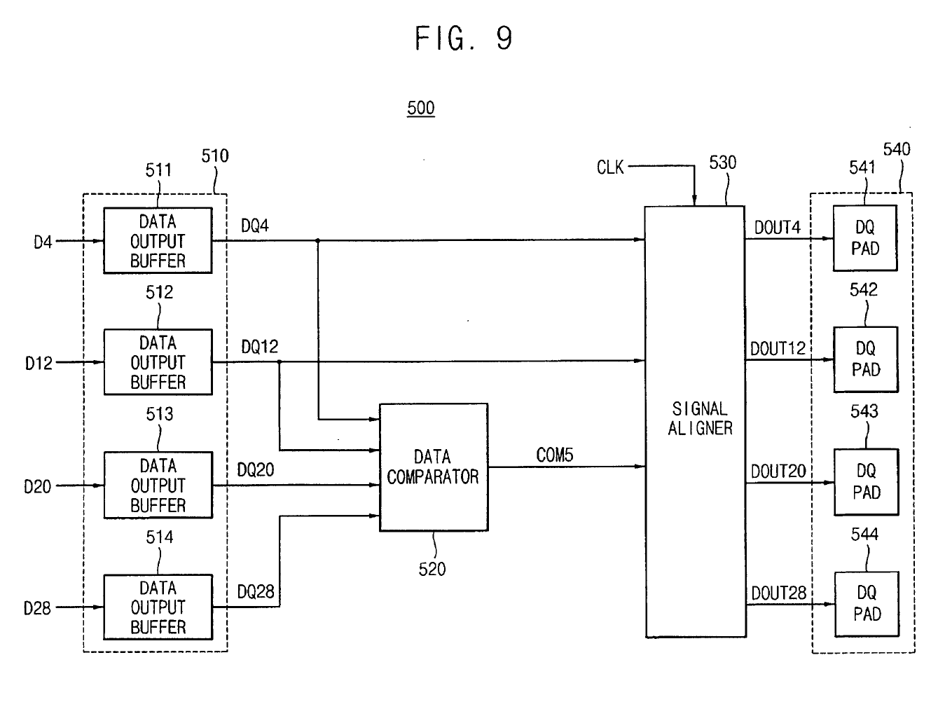

FIG. 9 is a block diagram illustrating an embodiment of a circuit for generating test data DOUT4, DOUT12, DOUT20 and DOUT28 based on output data DQ4, DQ12, DQ20 and DQ28 of the fifth output buffer circuit 510 in FIG. 4. Referring to FIG. 9, a test circuit 500 of the semiconductor memory device comprises an output buffer circuit 510, a data comparator 520, a signal aligner 530 and an output pad circuit 540.

The output buffer circuit 510, which corresponds to the output buffer circuit 510 in FIG. 4, includes data output buffers 511, 512, 513 and 514.

The data comparator 520 compares the output data DQ4, DQ12, DQ20 and DQ28 of the output buffer circuit 510 including first data output buffers 511 and 512 and second data output buffers 513 and 514, and generates a comparison signal COM5.

The signal aligner 530 aligns the output data DQ4 and DQ12 of the first data output buffers 511 and 512 and the comparison signal COM5 in response to the clock signal CLK and generates the test data DOUT4, DOUT12, DOUT20 and DOUT28. Each of the test data DOUT4, DOUT12, DOUT20 and DOUT28 includes even bit test data, odd bit test data, even bit comparison test data and odd bit comparison test data, respectively. The test data DOUT4, DOUT12, DOUT20 and DOUT28 can be transmitted to a test device through output pads 541, 542, 543, and 544 included in the output pad circuit 540, respectively.

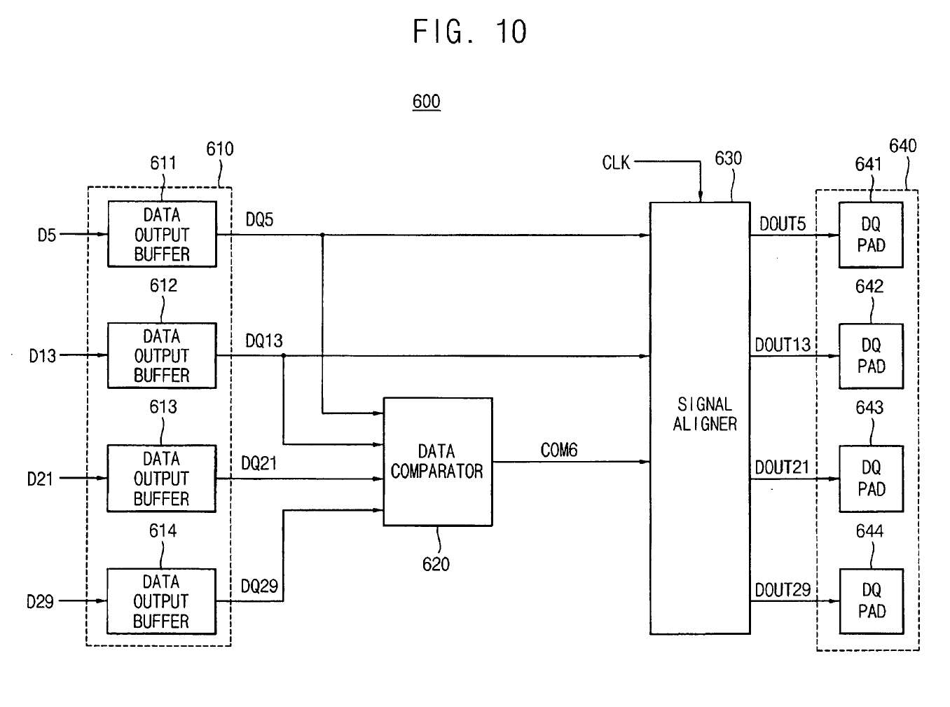

FIG. 10 is a block diagram illustrating an embodiment of a circuit for generating test data DOUT5, DOUT13, DOUT21 and DOUT29 based on output data DQ5, DQ13, DQ21 and DQ29 of the sixth output buffer circuit 610 in FIG. 4. Referring to FIG. 10, a test circuit 600 of the semiconductor memory device comprises an output buffer circuit 610, a data comparator 620, a signal aligner 630 and an output pad circuit 640.

The output buffer circuit 610, which corresponds to the output buffer circuit 110 in FIG. 4, includes data output buffers 611, 612, 613 and 614.

The data comparator 620 compares the output data DQ5, DQ13, DQ21 and DQ29 of the output buffer circuit 610 including first data output buffers 611 and 612 and second data output buffers 613 and 614, and generates a comparison signal COM6.

The signal aligner 630 aligns the output data DQ5 and DQ13 of the first data output buffers 611 and 612 and the comparison signal COM6 in response to the clock signal CLK and generates the test data DOUT5, DOUT13, DOUT21 and DOUT29. Each of the test data DOUT5, DOUT13, DOUT21 and DOUT29 includes even bit test data, odd bit test data, even bit comparison test data and odd bit comparison test data, respectively. The test data DOUT5, DOUT13, DOUT21 and DOUT29 can be transmitted to a test device through output pads 641, 642, 643 and 644 included in the output pad circuit 640, respectively.

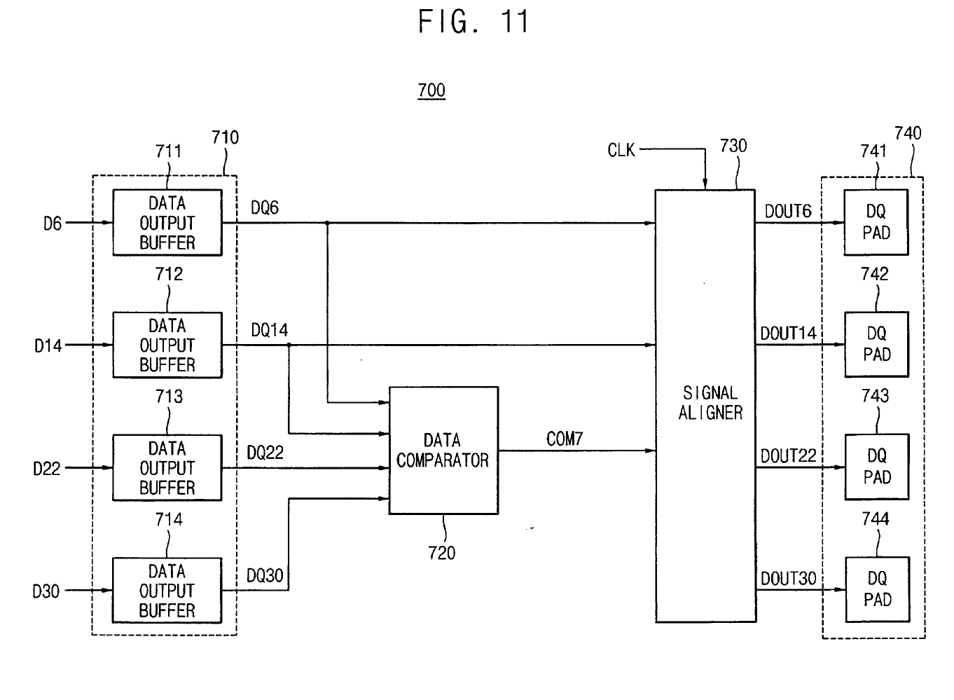

FIG. 11 is a block diagram illustrating an embodiment of a circuit for generating test data DOUT6, DOUT14, DOUT22 and DOUT30 based on output data DQ6, DQ14, DQ22 and DQ30 of the seventh output buffer circuit 710 in FIG. 4. Referring to FIG. 11, a test circuit 700 of the semiconductor memory device comprises an output buffer circuit 710, a data comparator 720, a signal aligner 730 and an output pad circuit 740.

The output buffer circuit 710, which corresponds to the output buffer circuit 710 in FIG. 4, includes data output buffers 711,712, 713 and 714.

The data comparator 720 compares the output data DQ6, DQ14, DQ22 and DQ30 of the output buffer circuit 710 including first data output buffers 711 and 712 and second data output buffers 713 and 714, and generates a comparison signal COM7.

The signal aligner 730 aligns the output data DQ6 and DQ14 of the first data output buffers 711 and 712 and the comparison signal COM7 in response to the clock signal CLK and generates the test data DOUT6, DOUT14, DOUT22 and DOUT30. Each of the test data DOUT6, DOUT14, DOUT22 and DOUT30 comprise even bit test data, odd bit test data, even bit comparison test data and odd bit comparison test data respectively. The test data DOUT6, DOUT14, DOUT22 and DOUT30 can be transmitted to a test device through output pads 741, 742, 743 and 744 included in the output pad circuit 740, respectively.

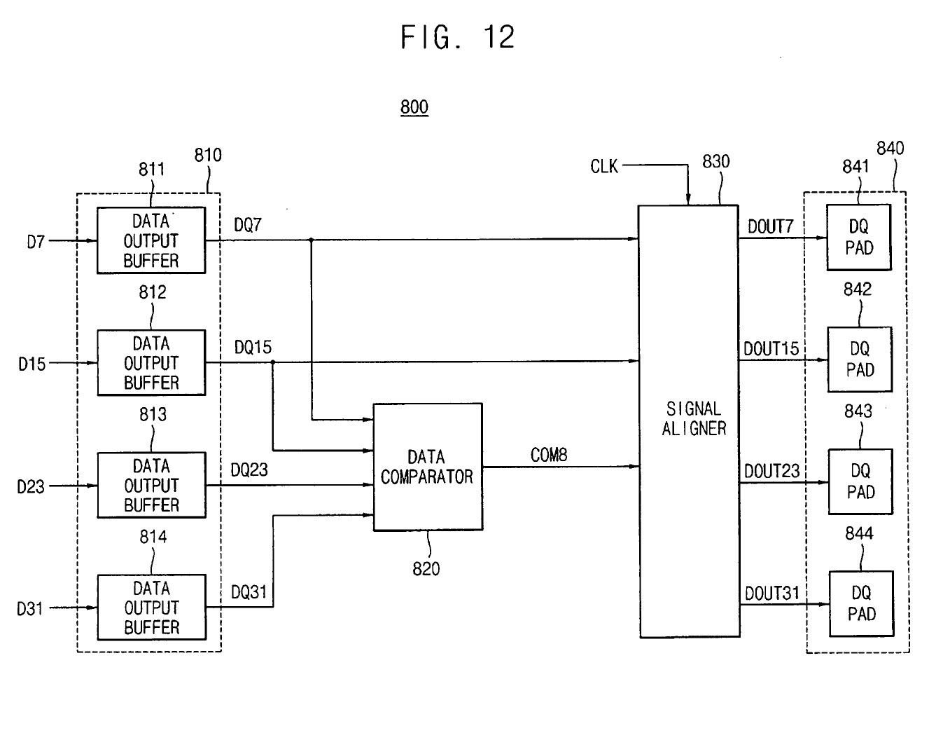

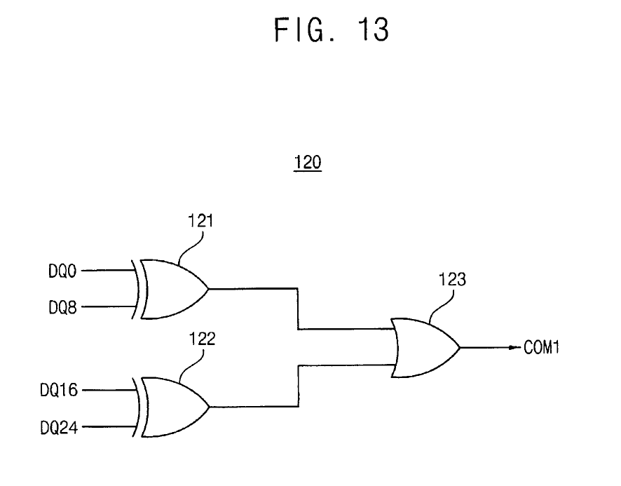

FIG. 12 is a block diagram illustrating an embodiment of a circuit for generating test data DOUT7, DOUT15, DOUT23 and DOUT31 based on output data DQ7, DQ15, DQ23 and DQ31 of the eighth output buffer circuit 810 in FIG. 4. Referring to FIG. 12, a test circuit 800 of the semiconductor memory device comprises an output buffer circuit 810, a data comparator 820, a signal aligner 830 and an output pad circuit 840.

The output buffer circuit 810, which corresponds to the output buffer circuit 310 in FIG. 4, includes data output buffers 811, 812, 813 and 814.

The data comparator 820 compares the output data DQ7, DQ15, DQ23 and DQ31 of the output buffer circuit 810 including first data output buffers 811 and 812 and second data output buffers 813 and 814 and generates a comparison signal COM8.

The signal aligner 830 aligns the output data DQ7 and DQ15 of the first data output buffers 811 and 812 and the comparison signal COM8 in response to the clock signal CLK and generates the test data DOUT7, DOUT15, DOUT23 and DOUT31. Each of the test data DOUT7, DOUT15, DOUT23 and DOUT31 includes even bit test data, odd bit test data, even bit comparison test data and odd bit comparison test data respectively. The test data DOUT7, DOUT15, DOUT23 and DOUT31 can be transmitted to a test device through output pads 841, 842, 843 and 844 included in the output pad circuit 840, respectively.

FIG. 13 is a circuit diagram illustrating an example of a data comparator that can be used in the test circuit of the semiconductor memory device in FIG. 5. The data comparators 220, 320, 420, 520, 620, 720, and 820 of FIGS. 6 through 12, respectively, can be similarly configured.

Referring to FIG. 13, the data comparator 120 includes XOR gates 121 and 122, and an OR gate 123. When logic states of the output data DQ0, DQ8, DQ16 and DQ24 are all “low” or all “high”, the comparison signal COM1 is logic “low”. When logic states of the output data DQ0, DQ8, DQ16 and DQ24 are not identical, the comparison signal COM1 is logic “high”.

Hereinafter, an operation of the test circuit of the semiconductor memory device according to example embodiments in accordance with aspects of the present invention will be described below with reference to FIGS. 3 through 13. The circuits of FIGS. 5 through 12 are included in the test circuit of the semiconductor memory device, in this example embodiment. For example, each test circuit from the circuits of FIGS. 5 through 12 processes four data from the 32 output data, i.e., DQ0 through DQ31, that are received from the output buffer circuits of FIG. 4. Accordingly, each of the circuits of FIGS. 5 through 12 generates four test data corresponding to its received output data.

Referring to FIG. 5, the data comparator 120 compares the output data DQ0, DQ8, DQ16 and DQ24, and determines whether logic states of the output data DQ0, DQ8, DQ16 and DQ24 are all identical. The data comparator 120 generates the comparison signal COM1 depending on the comparison result.

The signal aligner 130 receives the output data DQ0 and DQ8 of the data output buffers 111 and 112 and the comparison signal COM1. The signal aligner 130 aligns the output data DQ0 and DQ8 and the comparison signal COM1. That is, the signal aligner 130 latches the output data DQ0 and DQ8 and the comparison signal COM1, and generates the test data DOUT0, DOUT8, DOUT16 and DOUT24 in synchronization with the clock signal CLK.

The test data DOUT0, DOUT8, DOUT16 and DOUT24 can be even bit test data, the odd bit test data, the even bit comparison test data and odd bit comparison test data. The test data are outputted through different pads from the corresponding output pad circuit, here out pad circuit 140 having pads 141,142, 143, and 144 of FIG. 5, respectively.

For example, the test data DOUT0 can be even bit test data that is generated in response to the output data DQ0 and outputted through the output pad 141. The test data DOUT8 can be odd bit test data that is generated in response to the output data DQ8 and outputted through the output pad 142. The test data DOUT16 can be even bit comparison test data that is generated in response to the comparison signal COM1 and outputted through the output pad 143. The test data DOUT24 can be odd bit comparison test data that is generated in response to the comparison signal COM1 and outputted through the output pad 144. The output data DQ0, DQ8, DQ16 and DQ24 can be serial data including even bit data and odd bit data.

The data DOUT16 can be generated in response to the comparison signal COM1 when the output data DQ0, DQ8, DQ16 and DQ24 are even bit data and the data DOUT24 can be generated in response to the comparison signal COM1 when the output data DQ0, DQ8, DQ16 and DQ24 are odd bit data.

Therefore, the even bit test data is outputted through the output pad 141, the odd bit test data is outputted through the output pad 142. The even bit comparison test data is outputted through the output pad 143 and the odd bit comparison test data is outputted through the output pad 144.

The test circuits of the semiconductor memory device in FIGS. 6 through 12 operate in a similar way as the test circuit in FIG. 5, and thus further descriptions about operations of the circuits of FIGS. 6 through 12 are omitted.

The test circuits of the semiconductor memory device in FIGS. 5 through 12 can perform an I/O format test. The write data for testing a semiconductor memory cell array are all logic “1” or all logic “0” in a conventional test mode. However, in the test circuits of the semiconductor memory device according to example embodiments, logic states for writing data associated with an individual test circuit from the test circuits in FIGS. 5 through 12 need to be identical, but logic states for writing data pertaining to the different test circuits can be different from each other.

In addition, in the test circuit of the semiconductor memory device according to example embodiments, the test data are outputted not only in response to the comparison signal COM1 of the data comparator 120, but also in response to the output data DQ0 and DQ8 that have not passed through the data comparator 120. Therefore, a test circuit according to example embodiments of the present invention can yield a correct test result even when test data are all inverted. In the conventional test circuits, the test data are outputted through all of the output pads in response to the even output data at a first edge of the clock signal, and then the test data are outputted through all of the output pads in response to the odd output data at a second edge of the clock signal. Therefore, the read operation of the even data and the odd data cannot be simultaneously performed by using one pattern.

The test circuit of the semiconductor memory device according to an exemplary embodiment of the present invention includes the signal aligners 130, 230, 330, 430, 530, 630, 730 and 830 that latch a part of the output data DQ0 through DQ31 and the comparison signal to output the test data in synchronization with the clock signal CLK. Therefore, the even bit test data corresponding to the even bit output data, the odd bit test data corresponding to the odd bit output data, the even bit comparison test data corresponding to the comparison signal when the output data are the even bit data and the odd bit comparison test data corresponding to the comparison signal when the output data are the odd bit data can be generated at the rising edge or the falling edge of the clock signal CLK. That is, the even bit test data, the odd bit test data, the even bit comparison test data, and the odd bit comparison test data are outputted through different pads for one cycle of the high speed clock HSC.

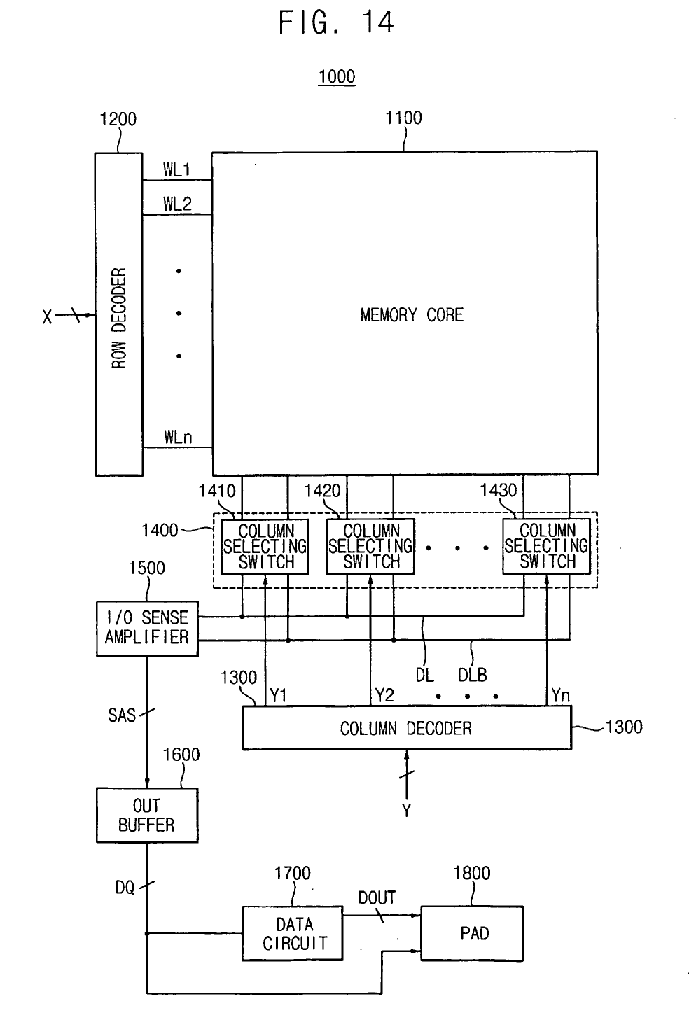

FIG. 14 is a block diagram illustrating an embodiment of a semiconductor memory device including the test circuit according to aspects of the present invention. Referring to FIG. 14, a semiconductor memory device 1000 includes a memory core 1100 including memory cell array, a row decoder 1200, a column decoder 1300, a column selecting switch circuit 1400, an I/O sense amplifier 1500, an output buffer circuit 1600, a test circuit 1700 and an output pad circuit 1800.

The row decoder 1200 decodes a low address signal X and generates word line selecting signals WL1, WL2, . . . , WLn. The memory cells included in the memory core 1100 are selected in response to the word line selecting signals WL1, WL2, . . . , WLn. The column decoder 1300 decodes a column address Y and generates column selecting signals Y1, Y2, . . . , Yn. The column selecting switches 1410, 1420 and 1430 included in the column selecting switch circuit 1400 receive the column selecting signals Y1, Y2, Yn, respectively, and transfer the data, which are received from the selected bit line pair, to the data line pair DL and DLB.

The I/O sense amplifier 1500 is enabled at the read operation and amplifies the sensed data difference received from the data line pair DL and DLB to generate a sense output signal SAS. The sense output signal SAS correspond to the 32 data D0 through D31 in FIG. 3. The output buffer circuit 1600 buffers the sense output signal SAS and generates the output data DQ. The output data DQ is outputted through the output pad circuit 1800 in the normal mode. The output pad circuit 1800 includes a plurality of pads. In the test mode, the test circuit 1700 receives the output data DQ and outputs the test data DOUT to the output pad circuit 1800.

Even though the test circuit of the semiconductor memory device having the X32 data structure is described above, those skilled in the art will understand that the present invention can be applied to a test circuit of the semiconductor memory device having any data structure.

As described above, the semiconductor memory device including the test circuit according to the present invention can simultaneously test the even bit data and the odd bit data by using one pattern so that a test time and a unit cost for testing can be decreased.

In addition, the semiconductor memory device having the test circuit according to the present invention outputs the test data not only in response to the comparison signal from the data comparator, but also in response to the output data that are not passed through the data comparator to output the test data, thereby yielding a correct test result even when test data are all inverted.

Having thus described exemplary embodiments of semiconductor test circuits and methods in accordance with aspects of the present invention, it is to be understood that the invention defined by the appended claims is not to be limited by particular details set forth in the above description as many apparent variations thereof are possible without departing from the spirit or scope thereof as hereinafter claimed. It is intended by the following claims to claim that which is literally described and all equivalents thereto, including all modifications and variations that fall within the scope of each claim.

What is claimed is:

1. A circuit for testing a semiconductor memory device comprising:
a data comparator configured to compare a first output data and a second output data provided from a output buffer circuit, and configured to determine whether logical states of the first output data and second output data are identical to generate a comparison signal; and
a signal aligner configured to align the first output data and the comparison signal, and configured to generate a plurality of test signals in response to a clock signal, the test signals including an even bit test data, an odd bit test data, an even bit comparison test data, and an odd bit comparison test data.

2. The circuit of claim 1, wherein the signal aligner is configured to align the first output data and the comparison signal by latching the first output data and the comparison signal, and is further configured to output the test signals in synchronization with the clock signal.

3. The circuit of claim 2, wherein the even bit test data and the odd bit test data are simultaneously outputted in response to a first edge of the clock signal, the first edge corresponding to one of a rising edge and a falling edged of the clock signal.

4. The circuit of claim 2, wherein the even bit comparison test data and the odd bit comparison test data are simultaneously outputted in response to a first edge of the clock signal, the first edge corresponding to one of a rising edge and a falling edged of the clock signal.

5. The circuit of claim 2, wherein the even bit test data, the odd bit test data, the even bit comparison test data and the odd bit comparison test data are outputted through different output pads from a set of output pads.

6. The circuit of claim 2, wherein the first output data comprises a third output data and a fourth output data, and the second output data comprises a fifth output data and a sixth output data.

7. The circuit of claim 6, wherein the even bit test data corresponds to an even bit of the third output data, and the odd bit test data corresponds to an odd bit of the fourth output data.

8. The circuit of claim 6, wherein the even bit comparison test data corresponds to the comparison signal when the third, fourth, fifth and sixth output data are even bit data and the odd bit comparison test data corresponds to the comparison signal when the first, second, third and fourth output data are odd bit data.

9. The circuit of claim 6, wherein the data comparator is configured to compare the third, fourth, fifth and sixth output data to generate the comparison signal.

10. The circuit of claim 9, wherein the data comparator comprises:
a first XOR gate configured to perform an XOR operation on the third and fourth output data to generate a first logic signal;
a second XOR gate configured to perform an XOR operation on the fifth and sixth output data to generate a second logic signal; and
an OR gate configured to perform an OR operation on the first and second logic signals to generate the comparison signal.

11. The circuit of claim 1, wherein the semiconductor memory device has an X32 output data structure, the X32 output data structure including four data groups, each data group including eight data.

12. The circuit of claim 11, wherein the semiconductor memory device operates with a burst length of four.

13. A semiconductor memory device comprising:
a memory core including a memory cell array; an Input/Output sense amplifier configured to amplify data outputted from the memory core to generate a sense output signal;
an output buffer circuit configured to buffer the sense output signal to generate a plurality of output data; and
a test circuit configured to process the plurality of output data to generate a plurality of test signals, the test circuit including:
a data comparator configured to compare a first output data and a second output data, and configured to determine whether logic states of the first and second output data are identical to generate a comparison signal; and
a signal aligner configured to align the first output data and the comparison signal, and configured to generate the test signals in response to a clock signal, the test data including even bit test data, odd bit test data, even bit comparison test data and odd bit comparison test data.

14. A method of testing a semiconductor memory device, the method comprising:
comparing a first output data and a second output data outputted from a sense amplifier to generate a comparison signal; and
aligning the first output data and the comparison signal to generate a plurality of test signals in response to a clock signal.

15. The method of claim 14, wherein the test signals comprise even bit test data, odd bit test data, even bit comparison test data and odd bit comparison test data.

16. The method of claim 15, wherein aligning the first output data and the comparison signal comprises latching the first output data and the comparison signal to output the test signals in synchronization with the clock signal.

17. The method of claim 16, wherein the even bit test data and the odd bit test data are simultaneously outputted in response to a first edge of the clock signal, the first edge corresponding to one of a rising edge and a falling edged of the clock signal.
